(19) United States
(12) Patent Application Publication
(10) Pub. No.: US 2014/0054605 A1
(43) Pub. Date: Feb. 27, 2014

(54) Composite Substrates, Light Emitting Devices and a Method of Producing Composite Substrates

(71) Applicant: NGK INSULATORS, LTD., Aichi-prefecture (JP)

(72) Inventors: Makoto Iwai, Kasugai-city (JP); Yoshitaka Kuraoka, Ozazaki-City (JP)

(73) Assignee: NGK INSULATORS, LTD., Aichi-prefecture (JP)

(21) Appl. No.: 14/064,421

(22) Filed: Oct. 28, 2013

Related U.S. Application Data
(63) Continuation of application No. PCT/JP2013/064818, filed on May 22, 2013.
(60) Provisional application No. 61/650,599, filed on May 23, 2012.

(51) Int. Cl. H01L 33/00; H01L 21/02; H01L 33/22; H01L 33/32; H01L 29/06; H01L 29/20

(52) U.S. Cl. CPC H01L 33/007; H01L 29/0657; H01L 29/2003; H01L 33/22; H01L 33/32; H01L 21/0242; H01L 21/0243; H01L 21/0254
USPC 257/76; 438/481

(57) ABSTRACT

A plurality of protrusions 3 are provided on a c-face 2a of a sapphire body 2. An underlying layer 5 made of gallium nitride is then grown by vapor phase epitaxy process on the c-face 2a. A gallium nitride crystal layer 6 is then provided by flux method on the underlying layer 5. Each of the protrusions 3 has a shape of a hexagonal prism or a six-sided pyramid. Differences of growth rates of the gallium nitride crystal around the protrusions 3 are utilized to relax a stress between the sapphire body and gallium nitride crystal and to reduce cracks or fractures due to the stress.

### FIELD OF THE INVENTION

The present invention relates to a composite substrate including a sapphire body and gallium nitride crystal grown thereon, a light emitting device and a method of producing a composite substrate.

### RELATED ART STATEMENTS

It is described a method of growing gallium nitride crystal on a sapphire body in Japanese Patent Publication Nos. 2000-021772A and 2001-168028A, for example.

### SUMMARY OF THE INVENTION

A seed crystal substrate is produced by forming GaN layer by MOCVD or the like on a c-face sapphire body with a flat surface and then used to grow GaN layer thereon by flux method at a growth temperature of 800 to 900° C. in a thickness of 10 to 100 μm, so that it can be produced a GaN template including the GaN layer with a low dislocation density and providing the uppermost surface.

The inventors have tried to produce an LED structure by MOCVD using this GaN template. During this trial, however, cracks or fractures were generated in the GaN layer of the GaN template at a high temperature (>1000° C.), which was problematic.

The cause of this phenomenon was speculated as follows. A thick film of GaN may be grown at a growth temperature of 800 to 900° C. by flux method, and the process temperature of MOCVD is elevated to 1000° C. or higher, so that the thick film of GaN could not endure the thermal stress applied thereon.

An object of the present invention is, in obtaining a composite substrate by growing gallium nitride crystal on a c-face of a sapphire body, to provide a structure of relaxing a thermal stress between the gallium nitride crystal and the sapphire body.

The present invention provides a composite substrate comprising:

a sapphire body comprising a c-face and a plurality of protrusions formed on said c-face; and

a gallium nitride crystal grown on said c-face,

wherein each of the protrusions has a shape of a hexagonal prism or a six-sided pyramid.

The present invention further provides a light emitting device comprising the composite substrate and a light emitting device structure provided on the gallium nitride crystal.

The present invention further provides a method of producing a composite substrate, the method comprising the steps of:

forming a plurality of protrusions on a c-face of a sapphire body, each of the protrusions having a shape of a hexagonal prism or a six-sided pyramid;

growing an underlying layer comprising gallium nitride on the c-face by a vapor phase epitaxy process; and

growing a gallium nitride crystal layer on the underlying layer by flux method.

According to the present invention, a stress due to a difference of thermal expansion coefficients of the gallium nitride layer and sapphire body can be reduced to obtain a GaN composite substrate with a small warping amount.

In the case that the GaN composite substrate is applied to a vapor phase epitaxy process, especially organic metal chemical vapor deposition method (MOCVD), it was found that cracks or fractures were not generated in the gallium nitride layer even under a high temperature (for example a temperature exceeding 1000° C.).

### BRIEF DESCRIPTION OF THE DRAWINGS

FIG. 1 shows the state that an underlying layer 5 of gallium nitride is formed on a sapphire body 2.

FIG. 2 in an enlarged view of a part of FIG. 1.

FIG. 3 in an enlarged view of a part of FIG. 1.

FIG. 4 shows a composite substrate 10 according to an embodiment of the present invention.

FIG. 5 shows a composite substrate 20 according to an embodiment of the present invention.

FIG. 6 shows an example of forming protrusions 3A each having a hexagonal shape in a plan view on a c-face 2a of a sapphire body 2A.

FIG. 7 shows an example of forming protrusions 3B each having a hexagonal shape in a plan view on a c-face 2a of a sapphire body 2B.

FIG. 8 shows an example of forming protrusions 3C each having a circular shape in a plan view on a c-face 2a of a sapphire body 2C.

FIG. 9 is a view schematically showing a period “D” of protrusions and a diagonal line width “E” of the protrusion in the microstructure shown in FIG. 2.

### EMBODIMENTS FOR CARRYING OUT THE INVENTION

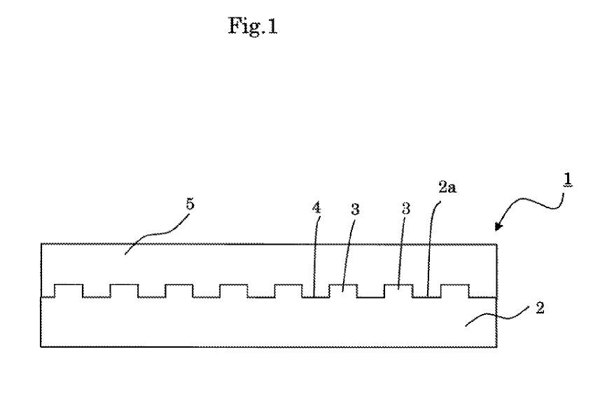

As shown in FIG. 1, a plurality of protrusions 3 are protruded on a c-face 2a of a sapphire body 2. Preferably, the protrusions 3 are regularly arranged in a plan view. This means that they are regularly arranged in at least one direction in a plan view, and they may be regularly arranged in two or more directions in a plan view. Preferably, the protrusions are arranged so as to be six-fold rotational symmetrical on the c-face in a plan view.

A distance between the protrusions may be constant.

The protrusion has a shape of a hexagonal prism or a six-sided pyramid.

A gap 4 between the adjacent protrusions 3 may be formed by a flat surface or an inclined surface.

An underlying layer 5 made of gallium nitride crystal is formed on the c-face 2a, preferably by vapor phase epitaxy process.

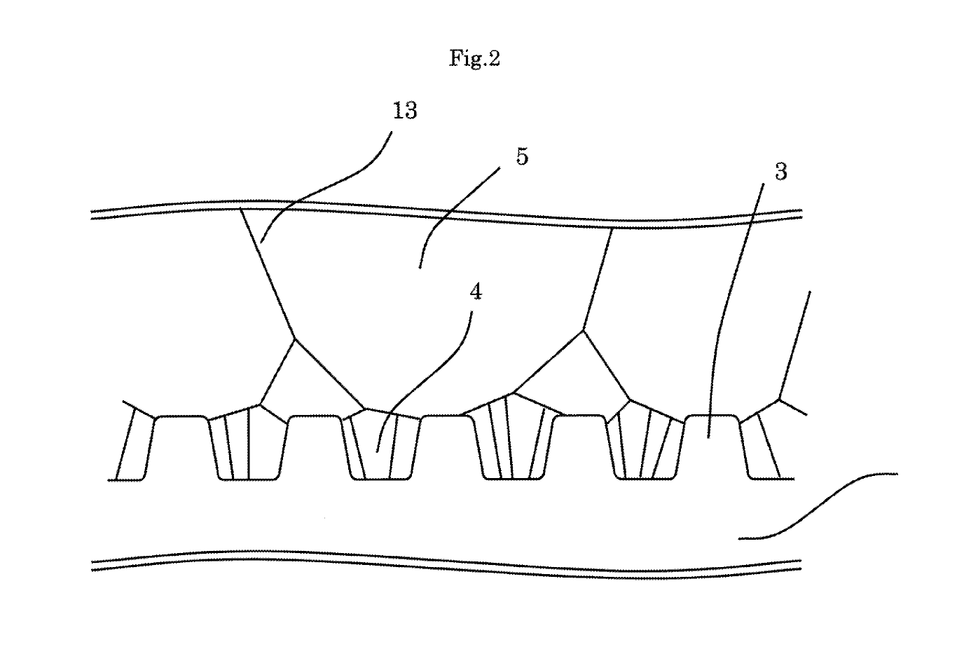

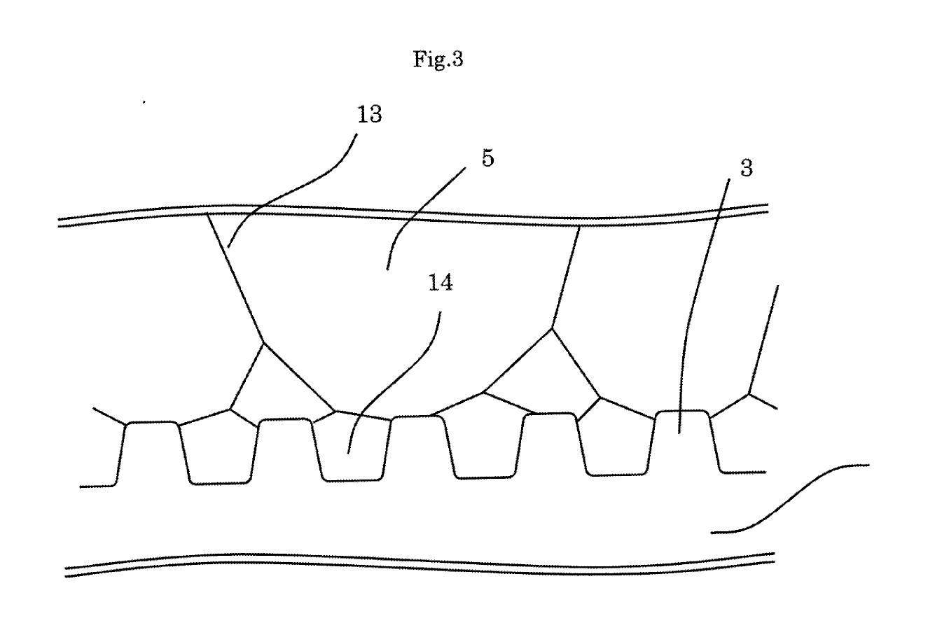

During the growth of the underlying layer 5, growth rates of gallium nitride crystal are different from each other depending on orientations of sapphire. As a result, during the production of a seed crystal substrate, the orientations of sapphire are different on an upper face and a side wall face of the protrusion 3, so that there is a difference between the growth rates of gallium nitride grown from the respective orientations. As a result, it is generated a layer, between the protrusions, where dislocations 13 are generated in concentrated manner to provide a structure of relaxing the stress (refer to FIG. 2). Alternatively, depending on the film-forming conditions, spaces 14 are formed, between the protrusions, where gallium nitride is not generated to provide a structure of relaxing the stress through the layer (FIG. 3). During the subsequent treatment at a high temperature, this reduces the cracks and fractures due to the thermal stress between the sapphire body and gallium nitride. It is possible to control the degree of relaxing of the stress, by designing the shape, dimensions and density of the protrusions.

It is possible to reduce the warping of the GaN composite substrate (template) by reducing the stress, and it is thereby expected an improvement of uniformity of luminous spectrum in a plane of a wafer during the production of an LED.

During the production of the seed crystal substrate 1, dislocations are united and disappeared by lateral growth, so that the crystallinity of gallium nitride is improved and the crystal quality of the GaN layer of the seed crystal substrate is improved (this idea itself is known as Epitaxially Lateral Overgrowth: ELO or ELOG method).

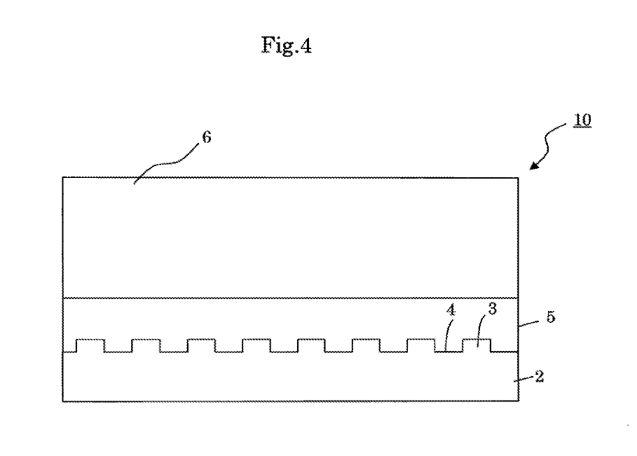

As a result, as shown in FIG. 4, in the case that a gallium nitride crystal layer 6 is formed on a seed substrate by flux method to obtain a GaN composite substrate 10, the crystal quality of the gallium nitride crystal layer 6 is improved.

It is known that, by producing the light emitting diode (LED) on a GaN composite substrate 10 by vapor phase epitaxy process, such as organic metal chemical vapor deposition (MOCVD) method, the dislocation density inside of the LED becomes comparable with that of the GaN template.

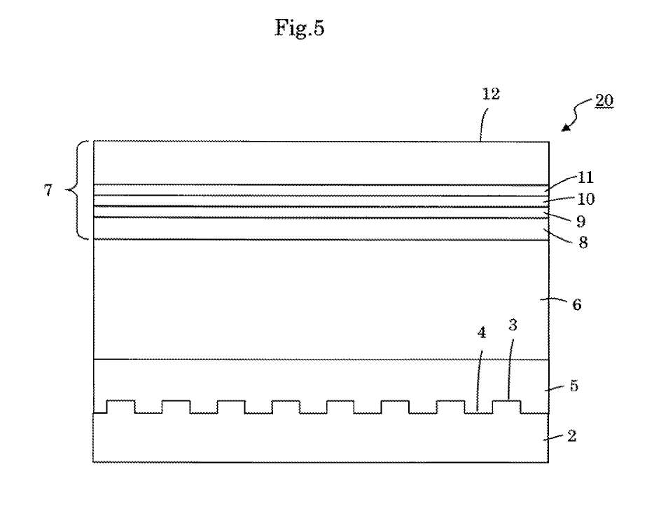

Therefore, by producing a semiconductor light emitting device structure 7 is formed, as shown in FIG. 5, on the GaN composite substrate shown in FIG. 4 obtained by the present invention, it is possible to obtain a light emitting layer having a low dislocation density to improve an internal quantum efficiency in a light emitting device 20.

The improvement of the light emitting efficiency by applying the present invention is expected to provide the synergistic effects with the improvement of the internal quantum efficiency of the light emission as described above.

Besides, the light emitting device structure 7 includes, for example, an n-type semiconductor layer, a luminous region provided on the n-type light emitting layer and a p-type semiconductor layer provided on the luminous region.

According to an example shown in FIG. 5, on the gallium nitride layer 6, an n-type contact layer 8, an n-type clad layer 9, an active layer 10, a p-type clad layer 11 and a p-type contact layer 12 are formed to fabricate a light emitting device structure 7.

At this time, it was found that the stress can be relaxed more effectively by applying the protrusions of a hexagonal prism or a six-sided pyramid shape than those of circular shape applied in PSS (Patterned sapphire substrate) conventionally supplied in a market. Although the reasons are not clear, the following principles of growth would be speculated.

Nuclei of GaN are generated on sites of exposed c-face excluding the hexagonal prism or a six-sided pyramid on the sapphire body, and the nuclei are then grown to island shaped parts, which are then connected with each other to produce a uniform film. Although GaN is grown at the m-face on side faces of the protrusion having a shape of a hexagonal prism or a six-sided pyramid, the growth rate is lower than that at c-face. Further, a top face of the protrusion is flat compared with its surrounding faces or is inclined with respect to the c-face, so that the nuclei are hardly formed thereon and the growth rate is lower than that at the side faces of the protrusions of a shape of a hexagonal prism or a six-sided pyramid. It is thereby susceptible to generation of spaces. Even if the spaces would not be generated, discontinuity tends to be generated along interfaces between growing regions from the side faces and those from the bottom face, so that the relax of the stress is facilitated.

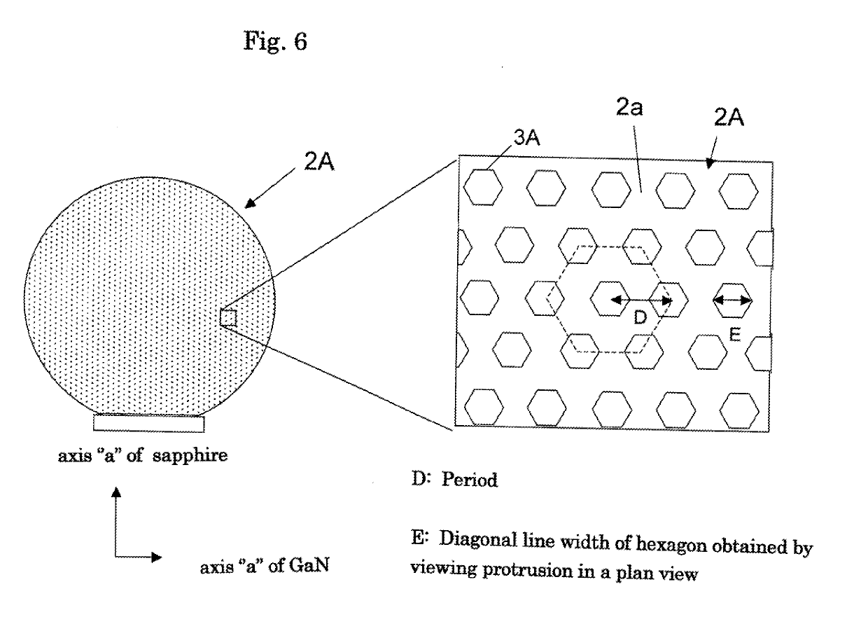

For example, according to a sapphire body 2A shown in FIG. 6, a plurality of protrusions 3A are formed on a c-face 2a. Each of the protrusions 3A has a shape of a hexagon in a plan view, and the protrusions 3A are arranged so as to be six-fold rotational symmetrical. That is, each of the protrusions 3A has a shape of a hexagon viewed from the above of the c-face of the body. The diagonal line width “E” of the hexagon obtained by viewing the hexagonal prism or six-sided pyramid forming the protrusion may preferably be 2 μm or more or 10 μm and may be 10 μm or less on the viewpoint of the present invention. Further, the period “D” of the protrusions may be 4 μm or larger and may be 20 μm or smaller on the viewpoint of the present invention. Further, “D/E” may preferably be 1 or larger and may be 3 or smaller on the viewpoint of the present invention.

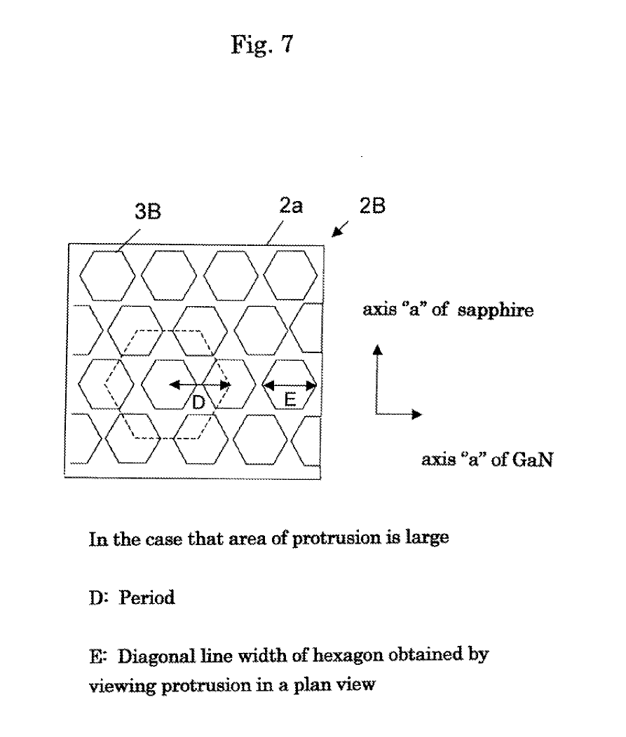

According to a sapphire body 2B shown in FIG. 7, a plurality of protrusions 3B are formed on a c-face 2a. Each of the protrusions 3B has a shape of a hexagon in a plan view, and the protrusions 3B are arranged so as to be six-fold rotational symmetrical. That is, each of the protrusions 3B has a shape of a hexagon viewed from the above of the c-face of the body. According to the example shown in FIG. 7, the ratio of diagonal line width “E”/period “D” is made larger than that in the example of FIG. 6.

(Applications)

The composite substrate of the present invention may be used in technical fields requiring high quality, including a white LED with improved color rendering index expected as a post-fluorescent lamp, and a blue-violet laser for high-speed and high-density optical memory, for example.

(Examples of Underlying Layer)

A material depositing the underlying layer may preferably be gallium nitride exhibiting yellow luminescence by observation using a fluorescence microscope. The yellow luminescence referred to herein means one which is emitted by ultraviolet irradiation such as mercury lamp or the like equipped with a fluorescence microscope, has a peak at a wavelength around 550 nm and has broad spectrum whose FWHM is about 50 to 100 nm. It may be close to orange rather than yellow in some cases.

The underlying layer may preferably be deposited by vapor phase epitaxy process, including metal organic chemical vapor deposition (MOCVD), hydride vapor phase epitaxy (HVPE), pulse excited deposition (PXD), Molecular Beam Epitaxy (MBE) and sublimation processes. Metal organic chemical vapor deposition process is particularly preferable.

According to the gallium nitride crystal exhibiting the yellow luminescence, it is observed, in addition to exciton transition (UV) from a band to a band, a broad peak in a range of 2.2 to 2.5 eV. This is called yellow luminescence (YL) or yellow band (YB).

By applying a fluorescence microscope, it is possible to excite only the yellow luminescence in this range and to detect the presence or absence of the yellow luminescence.

Such yellow luminescence is derived from radiation process relating to native defects, such as nitrogen defects, originally present in the crystal. Such defects cause luminescent centers. Probably, it is considered that impurities of transition metal such as Ni, Co, Cr, Ti derived from the reacting condition would be taken into the gallium nitride crystal to form the luminescent centers of the yellow band.

Such gallium nitride crystal exhibiting the yellow luminescence is exemplified in Japanese Patent Publication No. 2005-506271A, for example.

Preferably, the dislocation density of the gallium nitride crystal exhibiting the yellow luminescence is 10⁸ to 10⁹/cm², the FWHM of X-ray rocking curve measurement of (0002) plane is 250 arcsec. or lower, and the FWHM of X ray rocking curve measurement of (10-12) plane is 350 arcsec. or lower.

Further, the thickness of the underlying layer may preferably be 1 to 5 μm.

(Preferred Embodiments of Gallium Nitride Film Obtained by Liquid Phase Epitaxy Process)

According to a preferred embodiment, gallium nitride film by liquid phase epitaxy process is one which does not exhibit yellow luminescence by measurement applying a fluorescence microscope. The gallium nitride film may exhibit the following luminescence in the measurement by applying a fluorescence microscope.

Blue or blue-white luminescence (as a result of spectrum analysis, a broad luminescence having a peak wavelength at 450 to 460 nm and the FWHM of the spectrum is 30 to 50 nm.)

Although the thickness of the gallium nitride crystal by liquid phase epitaxy process is not limited, it may preferably be 50 μm or larger and more preferably be 100 μm or larger. As to the upper limit of the thickness, as the thickness is larger, the warping becomes larger, and the thickness may preferably be 0.2 mm or smaller on the viewpoint of the production.

Further, the gallium nitride crystal by liquid phase epitaxy process may preferably have a surface dislocation density at the c-face of 10⁶/cm² or smaller. Further, the gallium nitride crystal may contain a transition metal element such as Ti, Fe, Co, Cr or Ni. Further, it may preferably contain a donor, and/or an acceptor, and/or a magnetic dopant in a concentration of 10¹⁷/cm³ to 10²¹/cm³.

(Processing of Gallium Nitride Film by Liquid Phase Epitaxy Process)

The composite substrate may be utilized as a member for a device as it is. However, depending on the applications, it is possible to polish a surface of the gallium nitride film. As to the polishing, for example, it is ground using a fixed abrasive grains (grinding), then lapped using diamond slurry (lapping), and subjected to CMP (chemical mechanical polishing) using acidic or alkaline colloidal silica slurry.

Further, the thickness of the gallium nitride film by liquid phase epitaxy process after the polishing may preferably be 150 μm or smaller and more preferably be 100 μm or smaller.

For example, for applying the composite substrate in a white LED with improved color rendering index, an LED light source for head light for an automobile, a super high brightness LED and laser diode for a display such as of pure green ray, it is required to polish the surface of the gallium nitride film thus grown. For this, in the case that the warping of the gallium nitride film is small, it is easier to adhere it to a surface plate and to lessen a required amount of the polishing. Further, in the case that a light emitting layer is formed on the gallium nitride film by vapor phase epitaxy process, the quality of the light emitting layer is improved.

(Light Emitting Layer)

By producing the light emitting diode (LED) on the composite substrate by vapor phase epitaxy process, preferably by organic metal chemical vapor deposition (MOCVD) method, the dislocation density inside of the LED becomes comparable with that of the composite substrate.

The growth temperature of n-GaN of the light emitting layer may preferably be 1000° C. or higher and more preferably be 1050° C. or higher, on the viewpoint of quality of the formed film (prevention of surface pits). On the other hand, on the viewpoint of controlling indium composition in the light emitting layer, the growth temperature of the light emitting layer may preferably be 850° C. or lower and more preferably be 800° C. or lower.

The material of the light emitting layer may preferably be a nitride of a group 13 element. Group 13 element means group 13 element according to the Periodic Table determined by IUPAC. The group 13 element is specifically gallium, aluminum, indium, thallium or the like.

### EXAMPLES

### Example 1

### Processing of Sapphire Body

A resist having a thickness of 1 μm was patterned on a surface of a c-face sapphire body having a diameter of 2 inches and a thickness of 500 μm using photolithography. As to the resist pattern, the pattern was designed so that the hexagonal prisms, each having a diagonal line width “E” of 4 μm, were arranged at a period “D” of 6 μm so as to be six-fold rotational symmetrical. This was subjected to etching for 10 minutes using a chlorine-based dry etching system to etch the sapphire body to a depth of about 1.5 μm where it is not covered by the resist, to leave protrusions each having a shape of hexagonal prism where the resist was present. The residue of the resist was removed by a remover.

It was thereby obtained a sapphire body 2A as shown in FIG. 6. That is, a plurality of protrusions 3A were formed on a c-face 2a of the sapphire body 2A. Each of the protrusions 3A has a shape of a hexagonal prism, and the protrusions 3A were positioned so as to be six-fold rotational symmetrical. The diagonal line width “E” of the hexagon obtained by viewing the hexagonal prism forming the protrusion in a plan view was made 4 μm, and the period “D” of the hexagons was made 6 μm.

(Deposition of Underlying Layer)

A low temperature GaN buffer layer was deposited to 40 nm, on the sapphire body with the protrusions on the c-face, by MOCVD method at 530° C., and a GaN film was then deposited at 1050° C. to a thickness of 3 μm. After it was naturally cooled to room temperature, the warping of the substrate was measured. It was thus proved that the substrate has convex shape in the case that the face with the GaN film formed thereon was oriented upwardly, and the warping of the 2-inch wafer was proved to be about 20 μm, which was defined as a value of the maximum height minus the minimum height in the case that the substrate was placed on a flat plane.

By means of a differential interference contrast microscope, it was confirmed that small spaces (each having a size of about 1 μm) were sparsely generated between the protrusions on the sapphire body. It was ultrasonically washed with an organic solvent and ultra-pure water for 10 minutes, respectively, and then dried to provide a seed crystal substrate.

(Growth of GaN Crystal by Liquid Phase Epitaxy Process)

Then, gallium nitride was grown on an upper face of the seed crystal substrate by flux method.

An alumina crucible was used, and Ga metal and Na metal were weighed in a molar ratio of 18:82 and then placed on a bottom of the crucible with the seed crystal substrate.

According to the present example, the growth time period was made 20 hours to grow gallium nitride crystal having a thickness of 180 μm. It was thus proved that the substrate had convex shape in the case that the sapphire body was oriented downwardly, and the warping of the 2-inch wafer was proved to be about 250 μm, which was defined as a value of the maximum height minus the minimum height in the case that the substrate was placed on a flat plane.

The gallium nitride crystal was one which does not exhibit yellow luminescence by measurement using a fluorescence microscope. Further, the gallium nitride crystal may exhibit the whitish blue luminescence by measurement using the fluorescence microscope. Although the source of the luminescence was not clearly understood, it was proved to be characteristic to the present production method. It was proved that broad spectrum in a luminous wavelength range of 430 to 500 nm was obtained by means of PL spectrum measurement.

(Production of Composite Substrate)

The thus grown gallium nitride crystal was polished according to the following steps.

The surface of the crystal was made flat by grinding with grinding stones of fixed abrasive grains, lapped with loose abrasives such as diamond slurry, and then polished with acidic or alkaline CMP slurry.

The thickness of the gallium nitride crystal after the polishing was made 15 μm±5 μm on the viewpoint of the present invention. The warping of wafer after the polishing was about 80 μm at room temperature.

This was subjected to washing with a scrub (scrubbing using a brush), ultrasonic cleaning with super pure water, and then dried to provide the substrate for forming films of an LED structure.

(Film Formation for LED Structure)

Films of an LED structure were formed according to the following steps by MOCVD method. It was elevated from room temperature to 1050° C. over about 15 minutes, the substrate was held in an atmosphere of mixture of nitrogen, hydrogen and ammonia for 15 minutes to perform thermal cleaning, an n-GaN layer having a thickness of 2 μm was then deposited at 1050° C., the temperature was then descended to 750° C., and 10 pairs of multi quantum well structures (active layers) of InGaN/GaN were deposited. Further, an electron blocking layer of AlGaN was grown in 0.02 μm and the temperature was then elevated to 1000° C., p-GaN (p-clad layer, thickness of 80 nm) and p+GaN (p contact layer, thickness of 20 nm) were then deposited, and it was cooled to room temperature.

The substrate was taken out of an MOCVD furnace and observed by eyes to prove that cracks were not observed. Further, it was observed by a differential interference contrast microscope to prove that the surface was flat.

The wafer was used to produce LED devices of 0.3 mm square by conventional photolithography process. A voltage of about 3.5V was applied on electrodes of an LED and blue luminescence was observed at a wavelength of about 460 nm.

### Example 2

A c-face sapphire body having a diameter of 2 inches was etched by applying chlorine based dry etching in a depth of about 2 μm according to the same procedure as the Example 1, except that a thickness of the resist was made 0.5 μm, so that the shape of each protrusion was proved to be six-sided pyramid.

The sapphire body after the processing of the protrusions and recesses was used to form the underlying layer according to the same procedure as the Example 1. The warping was about 20 μm, and it was observed spaces, each having a size of 1 μm to several μm, between the protrusions. Thereafter, a GaN composite substrate was produced and films for an LED structure were then formed, according to the same procedure as the Example 1.

The substrate was taken out of the MOCVD furnace and then observed by eyes to prove that cracks were not observed. Further, it was observed by a differential interference contrast microscope to prove that the surface was flat.

The wafer was used to produce LED devices of 0.3 mm square by conventional photolithography process. A voltage of about 3.5 V was applied on electrodes of an LED and blue luminescence was observed at a wavelength of about 460 nm.

### Example 3

A c-face sapphire body having a diameter of 2 inches was etched by applying chlorine based dry etching in a depth of about 2 μm according to the same procedure as the Example 1, except that the period of the protrusions “D” was made 6 μm and the diagonal line width “E” of the hexagon was made 3 μm, so that the shape of each protrusion was proved to be hexagonal prism.

The sapphire body after the processing of the protrusions and recesses was used to form the underlying layer according to the same procedure as the Example 1. The warping was about 25 μm, and it was observed spaces, each having a size of 1 μm to several μm, between the protrusions. Thereafter, a GaN composite substrate was produced and films for an LED structure were then formed, according to the same procedure as the Example 1.

The substrate was taken out of the MOCVD furnace and then observed by eyes to prove that cracks were not observed. Further, it was observed by a differential interference contrast microscope to prove that the surface was flat.

The wafer was used to produce LED devices of 0.3 mm square by conventional photolithography process. A voltage of about 3.5 V was applied on electrodes of an LED and blue luminescence was observed at a wavelength of about 460 nm.

### Example 4

A c-face sapphire body having a diameter of 2 inches was etched by applying chlorine based dry etching in a depth of about 2 μm according to the same procedure as the Example 1, except that the period of the protrusions “D” was made 12 μm and the diagonal line width “E” of the hexagon was made 4 μm, so that the shape of each protrusion was proved to be hexagonal prism.

The sapphire body after the processing of the protrusions and recesses was used to form the underlying layer according to the same procedure as the Example 1. The warping was about 30 μm, and it was observed spaces, each having a size of 1 μm to several μm, between the protrusions. Thereafter, a GaN composite substrate was produced and films for an LED structure were then formed, according to the same procedure as the Example 1.

The substrate was taken out of the MOCVD furnace and then observed by eyes to prove that cracks were not observed. Further, it was observed by a differential interference contrast microscope to prove that the surface was flat.

The wafer was used to produce LED devices of 0.3 mm square by conventional photolithography process. A voltage of about 3.5 V was applied on electrodes of an LED and blue luminescence was observed at a wavelength of about 460 nm.

### Example 5

A c-face sapphire body having a diameter of 2 inches was etched by applying chlorine based dry etching in a depth of about 2 μm according to the same procedure as the Example 1, except that the period of the protrusions “D” was made 24 μm and the diagonal line width “E” of the hexagon was made 8 μm, so that the shape of each protrusion was proved to be hexagonal prism.

The sapphire body after the processing of the protrusions and recesses was used to form the underlying layer according to the same procedure as the Example 1. The warping was about 35 μm, and it was observed spaces, each having a size of 2 μm to 6 μm, between the protrusions. Thereafter, a GaN composite substrate was produced and films for an LED structure were then formed, according to the same procedure as the Example 1.

The substrate was taken out of the MOCVD furnace and then observed by eyes to prove that about five straight and narrow cracks, each having a length of 2 to 3 mm, were generated only in the outer peripheral region of the wafer.

The wafer was used to produce LED devices of 0.3 mm square by conventional photolithography process. A voltage of about 3.5V was applied on electrodes of an LED and blue luminescence was observed at a wavelength of about 460 nm.

### Example 6

A c-face sapphire body having a diameter of 2 inches was etched by applying chlorine based dry etching in a depth of about 2 μm according to the same procedure as the Example 1, except that the period of the protrusions “D” was made 20 μm and the diagonal line width “E” of the hexagon was made 10 μm, so that the shape of each protrusion was proved to be hexagonal prism.

The sapphire body after the processing of the protrusions and recesses was used to form the underlying layer according to the same procedure as the Example 1. The warping was about 30 μm, and it was observed spaces, each having a size of several micrometers, between the protrusions. Thereafter, a GaN composite substrate was produced and films for an LED structure were then formed, according to the same procedure as the Example 1.

The substrate was taken out of the MOCVD furnace and then observed by eyes to prove that cracks were no observed. Further, it was observed by a differential interference contrast microscope to prove that the surface was flat.

The wafer was used to produce LED devices of 0.3 mm square by conventional photolithography process. A voltage of about 3.5 V was applied on electrodes of an LED and blue luminescence was observed at a wavelength of about 460 nm.

### Example 7

A c-face sapphire body having a diameter of 2 inches was etched by applying chlorine based dry etching in a depth of about 2 μm according to the same procedure as the Example 1, except that the period of the protrusions “D” was made 4 μm and the diagonal line width “E” of the hexagon was made 2 μm, so that the shape of each protrusion was proved to be hexagonal prism.

The sapphire body after the processing of the protrusions and recesses was used to form the underlying layer according to the same procedure as the Example 1. The warping was about 25 μm, and it was observed spaces, each having a size of 1 to several micrometers, between the protrusions. Thereafter, a GaN composite substrate was produced and films for an LED structure were then formed, according to the same procedure as the Example 1.

The substrate was taken out of the MOCVD furnace and then observed by eyes to prove that cracks were no observed. Further, it was observed by a differential interference contrast microscope to prove that the surface was flat.

The wafer was used to produce LED devices of 0.3 mm square by conventional photolithography process. A voltage of about 3.5V was applied on electrodes of an LED and blue luminescence was observed at a wavelength of about 460 nm.

### Comparative Example 1

The experiment was carried out according to the same procedure as the Example 1, except that it was used a sapphire body whose c-face had not been subjected to the processing of protrusions and recesses.

The warping of the seed crystal substrate was about 40 μm, which was proved to be about two-fold of that in the Example 1. Further, it was observed by a differential interference contrast microscope to prove that the spaces observed in the Example 1 were not confirmed.

After the formation of the LED structure, it was taken out of the MOCVD furnace. It was thus proved that many (several tens of) straight and narrow cracks, each having a length of about 10 to 20 mm, were generated mainly in the outer peripheral region of the wafer. By microscopic observation, it was proved that the starting points of the cracks were present in the vicinity of an interface between the sapphire body and seed crystal layer. The cracks were not extended to the sapphire body and penetrate to the surface of the thus grown nitride film. It was further proved that the direction of the straight cracks were substantially parallel with the cleavage direction of GaN.

### Comparative Example 2

The experiment was carried out according to the same procedure as the Example 1, except that the planar shape of each protrusion was made circular and that its diameter was made same as the diagonal line width of the hexagon of the Example 1.

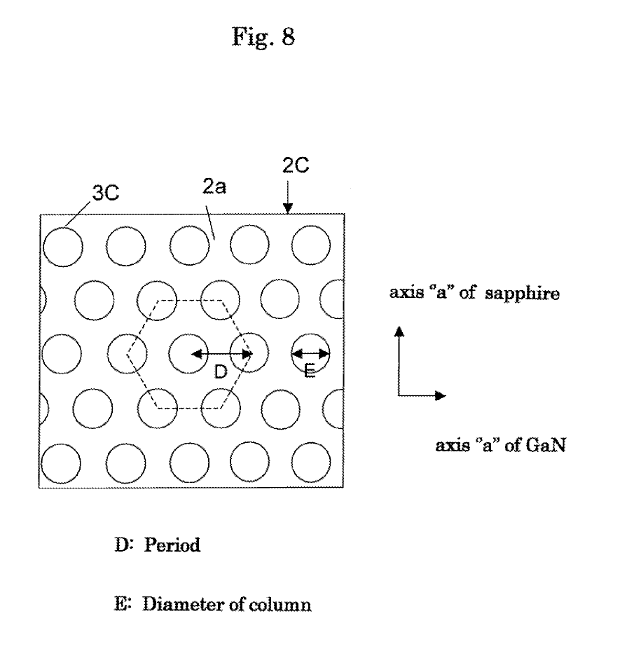

It was thus obtained a sapphire body 2C having a shape shown in FIG. 8. That is, a plurality of circular protrusions 3C were formed on a c-face 2a of a sapphire body 2C. Each protrusion 3C is circular in a plan view, and is substantially columnar, and the protrusions 3C are arranged so as to be six-fold rotationally symmetrical. The circle forming the protrusion had a diameter “E” of 4 μm and the protrusions had a period “D” of 6 μm.

The warping of the seed crystal substrate was about 35 μm, which was large and proved to be slightly lower than about two-fold of that in the Example 1. Further, it was observed by a differential interference contrast microscope to prove that the spaces observed in the Example 1 were not confirmed.

After the formation of the LED structure, it was taken out of the MOCVD furnace. It was thus proved that about ten straight and narrow cracks, each having a length of about 10 to 20 mm, were generated mainly in the outer peripheral region of the wafer.

### Comparative Example 3

The experiment was carried out according to the same procedure as the Example 2, except that the planar shape of each protrusion was made circular and that its diameter was made same as the diagonal line width of the hexagon of the Example 2.

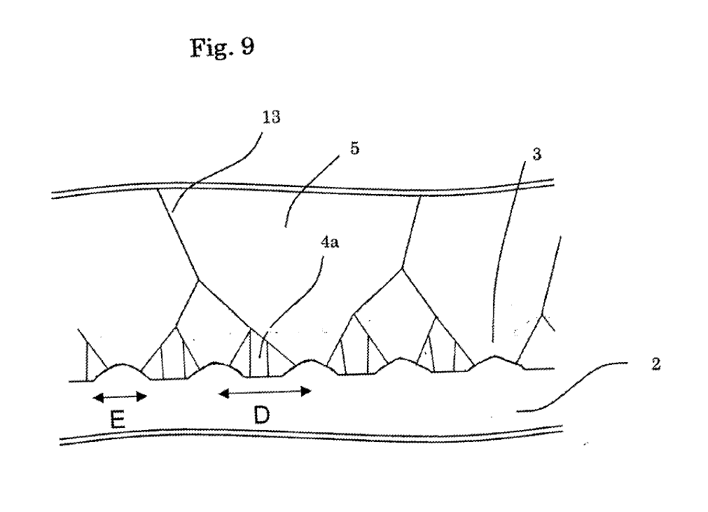

It was thus obtained a sapphire body 2C having a shape shown in FIG. 8. That is, a plurality of circular protrusions 3C were formed on a c-face 2a of the sapphire body 2C. Each protrusion 3C is circular in a plan view, and is substantially conical as shown in FIG. 9, and the protrusions 3C are arranged so as to be six-fold rotationally symmetrical. The circle forming the protrusion had a diameter “E” of 4 μm and the protrusions had a period “D” of 6 μm. 4a represents a dislocation concentrated layer.

The warping of the seed crystal substrate was about 35 μm, which was proved to be large and slightly lower than about two-fold of that in the Example. Further, it was observed by a differential interference contrast microscope to prove that the spaces observed in the Example 2 were not confirmed.

After the formation of the LED structure, it was taken out of the MOCVD furnace. It was thus proved that about ten straight and narrow cracks, each having a length of about 10 to 20 mm, were generated mainly in the outer peripheral region of the wafer.

### DESCRIPTION OF REFERENCE NUMERALS

1 Seed substrate
2, 2A, 2B, 2C Sapphire body
2a c-face of sapphire body
3, 3A, 3B, 3C Protrusions
4 Spaces between protrusions
4a Dislocation concentrated layer
5 Underlying layer of gallium nitride
6 Gallium nitride layer produced by flux method
7 Light emitting device structure
8 n-type contact layer
9 n-type clad layer
10 Active layer
11 p-type clad layer
12 p-type contact layer
13 Dislocation
14 Space

1. A composite substrate comprising:
a sapphire body comprising a c-face and a plurality of protrusions formed on said c-face; and
a gallium nitride crystal grown on said c-face,
wherein each of said protrusions has a shape of a hexagonal prism or a six-sided pyramid.

2. The composite substrate of claim 1, wherein said protrusions are arranged in six-fold rotational symmetry on said c-face.

3. The composite substrate of claim 1, wherein said protrusions are arranged in a period “D” of 20 μm or smaller.

4. The composite substrate of claim 1, wherein said gallium nitride crystal comprises an uppermost layer grown by flux method.

5. The composite substrate of claim 1, wherein said gallium nitride crystal comprises an underlying layer contacting said c-face and grown by a vapor phase epitaxy process.

6. A light emitting device comprising said composite substrate of claim 1 and a light emitting device structure provided on said gallium nitride crystal.

7. A method of producing a composite substrate, the method comprising the steps of:
forming a plurality of protrusions on a c-face of a sapphire body, each of said protrusions having a shape of a hexagonal prism or a six-sided pyramid;
growing an underlying layer comprising gallium nitride crystal on said c-face by a vapor phase epitaxy process; and
growing a gallium nitride crystal layer on said underlying layer by flux method.

8. The method of claim 7, wherein the step of forming a plurality of said protrusions comprises the step of subjecting said c-face of said sapphire body to etching to form said protrusions, and wherein said c-face of said sapphire body is flat before said etching.

9. The method of claim 7, wherein said protrusions are arranged in six-fold rotational symmetry on said c-face.
